(19) United States
(12) Patent Application Publication
(10) Pub. No.: US 2013/0093004 A1
(43) Pub. Date: Apr. 18, 2013

(54) SEMICONDUCTOR DEVICE INCLUDING DUMMY PILLAR NEAR INTERMEDIATE PORTION OF SEMICONDUCTOR PILLAR GROUP

(71) Applicant: ELPIDA MEMORY, INC., Tokyo (JP)

(72) Inventor: Yoshihiro TAKAISHI, Tokyo (JP)

(73) Assignee: ELPIDA MEMORY, INC., Tokyo (JP)

(21) Appl. No.: 13/651,786

(22) Filed: Oct. 15, 2012

(30) Foreign Application Priority Data
Oct. 14, 2011 (JP) 2011-226824

(51) Int. Cl. H01L 29/78

(52) U.S. Cl. 257/329; 257/E29.262

(57) ABSTRACT

A semiconductor device includes a semiconductor pillar group having semiconductor pillars which are formed in a first direction with a space left therebetween. A dummy pillar is disposed near a particular semiconductor pillar in the semiconductor pillar group in a second direction perpendicular to the first direction that is any one of the semiconductor pillars which are positioned in an intermediate portion exclusive of both end portions. Gate insulating films are formed on outer circumferential surfaces of the semiconductor pillars. One gate insulating film is formed on a part of an outer circumferential surface of the dummy pillar. Formed over side faces of the semiconductor pillars and over a side face of the dummy pillar via the gate insulating films, gate electrodes fill gaps between the semiconductor pillars and a gap between the particular semiconductor pillar and the dummy pillar.

This application is based upon and claims the benefit of priority from Japanese patent application No. 2011-226824, filed on Oct. 14, 2011, the disclosure of which is incorporated herein in its entirety by reference.

### BACKGROUND OF THE INVENTION

1. Field of the Invention

This invention relates to a semiconductor device, and in particular to a semiconductor device comprising a vertical transistor.

2. Description of Related Art

To take measures against finer design rules of transistors, a three-dimensional transistor having a vertical surround gate transistor (SGT) structure is known. The three-dimensional transistor is a transistor which uses, as a channel, a silicon pillar (a semiconductor pillar) extending along a direction (a Z direction) orthogonal to the principal plane (a XY plane defined by an X direction and a Y direction) of a semiconductor substrate. Herein, such as a three-dimensional transistor is simply referred to as a vertical transistor.

Various transistor devices each having such as a vertical transistor (the vertical SGT structure have been proposed heretofore.

By way of illustration, JP-A-2009-081389 (which will be also called Patent Document 1 and which corresponds to US 2009/0085102 A1) discloses a semiconductor device comprising four semiconductor pillars (silicon pillars) each having a size which allows full depletion and which are arranged in two directions of X and Y, gate insulating films formed on outer circumferential surfaces of the plurality of pillars, and gate electrodes covering side faces of the plurality of pillars so as to fill gaps between the plurality of pillars. That is, Patent Document 1 discloses the semiconductor device (the vertical transistor) having a characteristic equivalent to that of a structure in which a plurality of unit transistors are arranged in parallel. The gate electrodes formed to the side faces of the semiconductor pillars (the silicon pillars) make contact with each other to serve as a single gate electrode. Around a silicon pillar group comprising the plurality of silicon pillars, a gate-lifting silicon pillar (a dummy pillar) is formed in order to feed a gate voltage to the gate electrode.

As disclosed in Patent Document 1, the vertical transistor comprises the four silicon pillars arranged in the two directions of X and Y. In addition, the dummy pillar for feeding the gate voltage is disposed in an active region in which the four silicon pillars are disposed. However, in order to configure a semiconductor integrated circuit, there is a case to use a vertical transistor in which a plurality of semiconductor pillars (silicon pillars) are connected in parallel by linearly arranging the plurality of semiconductor pillars in a predetermined one direction and by arranging the dummy pillar for feeding the gate voltage at one end of this arrangement on an extension line thereof.

However, in the vertical transistor in which the plurality of semiconductor pillars are connected in parallel by linearly arranging the plurality of semiconductor pillars in the predetermined one direction and by arranging the dummy pillar for feeding the gate voltage at the one end of this arrangement on the extension line thereof, when the gate voltage is supplied to the gate electrode from the dummy pillar arranged at the one end on the extension line, there is a problem as follows. That is, if a poor forming of the semiconductor pillar adjacent to the dummy pillar occurs in the semiconductor pillars arranged in the predetermined one direction so that the semiconductor pillar in question is not formed, the gate electrodes are broken at this portion and it may be in danger of a poor operation of all of the unit transistors up to another end portion.

### SUMMARY

The present invention seeks to solve one or more of the above problems, or to improve upon those problems at least in part.

In one embodiment, there is provided a semiconductor device that includes a semiconductor pillar group comprising a plurality of semiconductor pillars which are formed in a first direction with a space left therebetween; a dummy pillar disposed in a second direction perpendicular to a first direction near a particular semiconductor pillar in the semiconductor pillar group that is any one of the semiconductor pillars positioned in an intermediate portion exclusive of bath end portions; gate insulating films which are formed on outer circumferential surfaces of the plurality of semiconductor pillars and one of which is formed on an outer circumferential surface of the dummy pillar; and gate electrodes formed over side faces of the plurality of semiconductor pillars and over a side face of the dummy pillar so as to fill gaps between the plurality of semiconductor pillars and a gap between the particular semiconductor pillar and the dummy pillar.

### BRIEF DESCRIPTION OF THE DRAWINGS

The above features and advantages of the present invention will be more apparent from the following description of certain preferred embodiments taken in conjunction with the accompanying drawings, in which:

FIG. 1A is a plan view of a semiconductor device a first example of this invention;

FIG. 1B is a cross-sectional view taken on line X1-X1′ of FIG. 1A;

FIG. 1C is a cross-sectional view taken on line Y1-Y1′ of FIG. 1A;

FIG. 2A is a plan view showing a process for forming a shallow trench isolation (STI) in a silicon substrate;

FIG. 2B is a cross-sectional view take on line X1-X1′ of FIG. 2A;

FIG. 3B is a cross-sectional view taken on line X1-X1′, showing a process for forming an insulating film and a mask film on an entire surface of the silicon substrate to pattern the insulating film and the mask film;

FIG. 4A is a plan view showing a process for forming five silicon pillars and a dummy pillar by dry-etching the silicon substrate exposed as the mask film as a mask;

FIG. 4B is a cross-sectional view taken on line X1-X1′ of FIG. 4A;

FIG. 4C is a cross-sectional view taken on line Y1-Y1′ of FIG. 4B;

FIG. 5B is a cross-sectional view taken on line X1-X1″, showing a process for forming sidewall films on side faces of the five silicon pillars, of the dummy pillar, and of the mask films and for forming first insulating films on exposed parts of the silicon substrate;

FIG. 6B is a cross-sectional view taken on line X1-X1′, showing a process of forming pillar lower diffused layers (drain diffused layers) under the first insulating films by ion implantation and for removing the sidewall films and thermal oxide films;

FIG. 7A is a plan view showing a process for forming gate insulating films to side faces of the five silicon pillars and of the dummy pillar and for forming gate electrodes on the side faces the five silicon pillars and of the dummy pillar alone;

FIG. 7B is a cross-sectional view taken on line X1-X1′ of FIG. 7A;

FIG. 7C is a cross-sectional view taken on line Y1-Y1′ of FIG. 7A;

FIG. 8B is a cross-sectional view taken on line X1-X1′, showing a process for forming a first interlayer insulating film so as to imbed the five silicon pillars and the dummy pillar and for forming a mask film;

FIG. 9B is a cross-sectional view taken on line X1-X1′, showing a process for forming a first opening portion by removing a part of the mask film and for forming second opening portions over the silicon pillars by removing the insulating film;

FIG. 10B is a cross-sectional view taken on line X1-X1′, showing a process for forming insulating films on inner walls of the second opening portions, for forming pillar upper diffused layers (source diffused layers) by implanting impurities from the second opening portions, for forming sidewall films to the inner walls of the second opening portions, and for exposing upper surfaces of the silicon pillars by removing the insulating films formed on the upper surfaces of the silicon pillars;

FIG. 11B is a cross-sectional view taken on line X1-X1′, showing a process for growing silicon plugs on the upper surfaces of the silicon pillars so as to stop up the second opening portions to make electrically contact with the pillar upper diffused layers (the source diffused layers);

FIG. 12B is a cross-sectional view taken on line X1-X1′, showing a process for depositing a second interlayer insulating layer, for depositing a stopper film, and for depositing a third interlayer insulating layer;

FIG. 13A is a plan view showing a process for forming contact holes;

FIG. 13B is a cross-sectional view taken on line X1-X1′ of FIG. 13A;

FIG. 13C is a cross-sectional view taken on line Y1-Y1′ of FIG. 13A;

FIG. 14A is a plan view showing a process for forming metal contact plugs by embedding metal films in the insides of the contact holes;

FIG. 14B is a cross-sectional view taken on line X1-X1′ of FIG. 14A;

FIG. 14C is a cross-sectional view taken on line Y1-Y1′ of FIG. 14A;

FIG. 15A is a plan view of a semiconductor device a second example of this invention; and

FIG. 15B is a cross-sectional view taken on line X1-X1′ of FIG. 15A.

### DETAILED DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

### Example 1

Referring now to Figures, a first example of this invention will be described.

The drawings for use in description herein are for the sake of describing the respective configurations and there may be cases where sizes, number, and so on in respective configurations are different from those of actual configurations. In addition, an XYZ coordinate system is set and arrangements of respective components will be described. In this coordinate system, the Z direction is a direction orthogonal to a surface of a silicon substrate, the X direction is a direction orthogonal to the Z direction in a horizontal surface concerning to the surface of the silicon substrate, and the Y direction is a direction orthogonal to the X direction in the horizontal surface concerning to the surface of the silicon substrate. In addition, the Y direction is also called a first direction while the X direction is also called a second direction. In the example being illustrated, the Y direction is a predetermined direction while the X direction is a direction orthogonal to the predetermined direction.

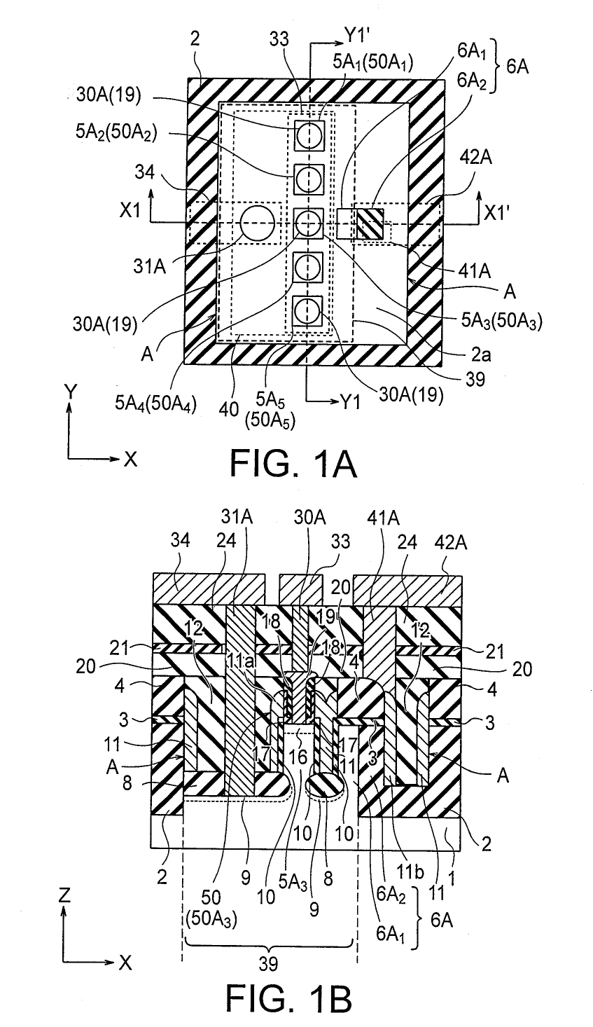

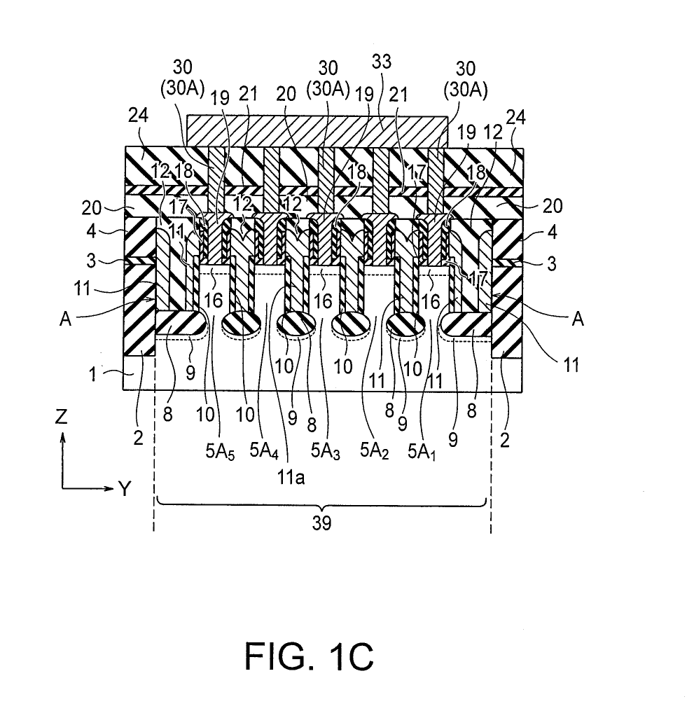

FIGS. 1A, 1B, and 1C are schematic views showing a configuration of a semiconductor device according to the first example of this invention. FIG. 1A is a plan view of the semiconductor device the first example. FIG. 1B is a cross-sectional view taken on line X1-X1′ of FIG. 1A. FIG. 1C is a cross-sectional view taken on line Y1-Y1′ of FIG. 1A. However, in FIG. 1A, in order to define a layout condition of components, interlayer insulating films and wires positioned on contact plugs are put into a transmittance state and only in outline thereof is described.

Referring now to FIGS. 1B and 1C, a shallow trench isolation (STI) 2 serving as an element isolation region is provided in the silicon substrate at depicted at 1. Five silicon pillars 5A are provided in a standing manner around the center of an active region 39 surrounded by the STI 2. Herein, in the Y direction (the first direction) of FIG. 1C, the five silicon pillars 5A are distinctly depicted as first through fifth silicon pillars 5A₁ to 5A₅ in the order towards from the right hand to left hand, respectively. In addition, the first through the fifth silicon pillars 5A₁ to 5A₅ are collectively called a silicon pillar group 5. Furthermore, each silicon pillar is also called a “semiconductor pillar.” That is, the silicon pillar group 5 comprises a plurality of silicon pillars 5A₁ to 5A₅ which are arranged in the first direction (the Y direction) with a space left therebetween. The silicon pillar group 5 is also called a semiconductor pillar group.

Each silicon pillar 5A comprises a semiconductor layer having a pillar shape that forms a channel portion of a unit transistor 50A. Herein, five unit transistors 50A are distinctly depicted as first through fifth unit transistors 50A₁ to 50A₅ which correspond to the first through the fifth silicon pillars 5A₁ to 5A₅, respectively. In addition, the first through the fifth unit transistors 50A₁ to 50A₅ are collectively also called a unit transistor group 50.

The first through the fifth silicon pillars 5A₁ to 5A₅ are arranged in the active region 39 partitioned by the STI 2 so as to have the same height entirely. Each silicon pillar 5A has a thickness (i.e., the size of the cross-section thereof in a plane parallel to the silicon substrate 1) which allows full depletion.

Impurity diffused layers are provided on an upper end portion and a lower end portion of each silicon pillar 5A. A pillar upper diffused layer 16 positioned on the upper end portion of each silicon pillar 5A comprises a source diffused layer while a pillar lower diffused layer 9 positioned on the lower end portion of each silicon pillar 5A comprises a drain diffused layer. A central portion of the silicon pillar 5A that is sandwiched between the pillar upper diffused layer 16 and the pillar lower diffused layer 9 acts as a channel portion.

As shown in FIG. 1A, a dummy pillar 6A is disposed so as to be adjacent to the third silicon pillar 5A₃ in the X direction that is positioned at a central portion of the silicon pillar group 5 comprising the first through the fifth silicon pillars 5A₁ to 5A₅. The dummy pillar 6A is disposed at a position extending over an active region 39 and the STI 2 and comprises a dummy silicon pillar 6A₁ positioned at the active region 39 side and an insulating layer pillar 6A₂ positioned at the STI 2 side. The dummy pillar 6A constitute a composite pillar into which the dummy silicon pillar 6A₁ and the insulating layer pillar 6A₂ are incorporated so that one side surface of the dummy silicon pillar 6A₁ and one side surface of the insulating layer pillar 6A₂ make contact with each other. Among side faces of the dummy silicon pillar 6A₁, one side face making contact with the insulating layer pillar 6A₂ is positioned on the other side of another side face which is disposed so as to oppose to one side face of the third silicon pillar 5A₃. The third silicon pillar 5A₃ is also called a particular semiconductor pillar.

As shown in FIGS. 1B and 1B, the five silicon pillars 5A and the dummy silicon pillar 6A₁ are formed by etching a surface of the silicon substrate 1 in the active region 39. The dummy silicon pillar 6A₁ comprises a semiconductor layer having a pillar shape that protrudes from the etched surface of the silicon substrate 1. The insulating layer pillar 6A₂ is formed by etching a surface of the STI 2 and comprises an insulating layer having a pillar shape that protrudes from the etched surface of the STI 2. The dummy pillar 6A has one side face to which a feeding gate electrode 11b is disposed. In addition, each silicon pillar 5A has one side face to which a transistor gate electrode 11a is disposed. A description of a gate electrode 11 is used to a common description of the transistor gate electrode 11a and the feeding gate electrode 11b. The gate electrode 11 is configured so that the transistor gate electrodes 11a and the feeding electrode 11b are mutually connected by burying a space between the particular semiconductor pillar and the dummy pillar 6A.

The dummy pillar 6A functions as a protruding layer which increases the height of the gate electrode 11 and which shortens the distance between the feeding gate electrode 11b and a gate-lifting wire 42A provided above the gate electrode 11. Each of the interval between adjacent silicon pillars 5A and the interval between the dummy pillar 6A and the particular silicon pillar 5A₃ (i.e. the width of a gap in the X direction between the particular silicon pillar 5A₃ and the dummy pillar 6A) is double or less the thickness of each gate electrode 11. The gate-lifting ware 42A is also called a gate wire simply.

The dummy pillar 6A is also called a “gate feeding dummy pillar” because it is used for supplying the transistor gate electrodes 11a with a gate voltage in the manner which will later be described.

As shown in FIG. 1A, the dummy pillar 6A is provided in the second direction (the X direction) orthogonal to the first direction (the Y direction) so as to be adjacent to the silicon pillar (in the example being illustrated, the particular silicon pillar 5A₃) which is positioned at an intermediate portion of the silicon pillar group 5. Among the instant specification, the “intermediate portion” means a part except for both end portions. In addition, in the example being illustrated, the both end portions correspond to the first and the fifth silicon pillars 5A₁ and 5A₅. Accordingly, in the example being illustrated, the “intermediate portion” corresponds to the second through the fourth silicon pillars 5A₂ to 5A₄.

In the manner which is the example being illustrated, it is preferable that the dummy pillar 6A is provided in the second direction orthogonal to the first direction so as to be adjacent to the particular silicon pillar 5A₃ which is position to the central portion of the silicon pillar group 5. However, the dummy pillar 6A may be provided in the second direction orthogonal to the first direction so as to be adjacent to a particular silicon pillar among the plurality of silicon pillars 5A₁ to 5A₅ arranged in the first direction that is any one of the silicon pillars 5A₂ to 5A₄ which are positioned in the intermediate portion except for the both end portions.

As shown in FIGS. 1B and 1C, a first insulating film 8 is formed on the surface of the silicon substrate 1 that is drilled by etching the active region 39 positioned around the respective silicon pillars 5A and the dummy silicon pillar 6A₁. The first insulating film 8 covers the peripheries of the lower portions of the respective silicon pillars 5A and the periphery of the lower portion of the dummy silicon pillar 6A₁, and reaches the STI 2. The pillar lower diffused layer 9 is provided under the first insulating film 8 so as to overlap the first insulating film 8. Thus, the first insulating film 8 is formed between the gate electrodes 11 and the pillar lower diffused layers 9, so that the pillar lower diffused layers 9 are electrically insulated from the gate electrodes 11 by means of the first insulating film 8. The first through the fifth silicon pillars 5A₁ to 5A₅ are electrically connected to each other by the pillar lower diffused layer 9. The pillar lower diffused layer 9 acts as a common drain section of the unit transistor group 50 (the first through the fifth unit transistors 50A₁ to 50A₅). It is noted that the STI 2 is formed deeper than the pillar lower diffused layers 9 so that the pillar lower diffused layer 9 respectively provided in areas which are adjacent across the STI 2 does not conduct each other.

Gate insulating films 10 are formed on side faces of the respective silicon pillars 5A and of the dummy silicon pillar 6A₁. The transistor gate electrodes 11a are disposed over the side faces of the respective silicon pillars 5A with the gate insulating films 10 interposed therebetween. In addition, the feeding gate electrode 11b is disposed over the side face of the dummy silicon pillar 6A₁. The gate electrodes 11 are also formed on a side face of the insulating layer pillar 6A₂, the inner wall of the STI 2, the inner walls of the insulating films 3 which are stacked on the top surface of the STI 2, and parts of the inner walls of the mask films 4. The gate insulating films 10 cover the side faces of the respective silicon pillars 5A, and are connected to the first insulating films 8. The channel portions of the respective silicon pillars 5A, the pillar upper diffused layers 16, and the pillar lower diffused layers 9 disposed the lower portions of the first insulating films 8 are electrically insulated from the gate electrodes 11 by means of the gate insulating films 10 and the first insulating films 8.

The intervals between the respective silicon pillars are double or less the thickness of each gate electrode 11.

The transistor gate electrodes 11a formed over the side faces of the respective silicon pillars 5A via the gate insulating films 10 are integrated by making contact with each other in the areas where the intervals of adjacent silicon pillars 5A are double or less the thickness of each transistor gate electrode 11a and act as a signal gate electrode shared in the respective silicon pillars 5A. The transistor gate electrodes 11a are filled in the gaps between the adjacent silicon pillars 5A in the height direction of the respective silicon pillars 5A on the whole.

The interval between the dummy pillar 6A and the third silicon pillar (the particular silicon pillar) 5A₃ positioned at the central portion of the silicon pillar group 5 is double or less the thickness of each gate electrode 11. Hence, the transistor gate electrode 11a disposed to the side face of the third silicon pillar 5A₃ and the feeding gate electrode 11b disposed to the side face of the dummy pillar 6A make contact with each other in the areas where the intervals of the respective pillars are double or less the thickness of each gate electrode 11 and are connected to each other.

Accordingly, supplied from a gate feeding wire of an upper layer against the feeding gate electrode 11b of the dummy pillar 6A, a gate voltage is applied to the transistor gate electrodes 11a shared in the respective silicon pillars 5A via the third silicon pillar 5A₃.

More specifically, the semiconductor device according to the first example comprises:

the semiconductor pillar group (5) comprising the plurality of semiconductor pillars (5A₁-5A₅) which are disposed in the first direction (Y) with the space left therebetween;

the dummy pillar (6A) disposed in the second direction (X) perpendicular to the first direction (Y) near the particular semiconductor pillar (5A₃) in the semiconductor pillar group (5) that is any one of the semiconductor pillars (5A₂-5A₄) positioned in the intermediate portion exclusive of the bath end portions;

the gate insulating films (10) which are formed on the side faces of the plurality of semiconductor pillars (5A₁-5A₅) and one of which is formed on a part of the side face of the dummy pillar (6A); and

the gate electrodes (11) formed over the side faces of the plurality of semiconductor pillars (5A₁-5A₁) and over the side face of the dummy pillar (6A) so as to fill the gaps between the plurality of semiconductor pillars (5A₁-5A₅) and the gap between the particular semiconductor pillar (5A₃) and the dummy pillar (6A).

Insulating films 3 and mask films 4 are disposed on top faces of the STI 2, of the respective silicon pillars 5, and of the dummy pillar 6A. A first interlayer insulating film 12 is formed so as to cover the gate electrodes 11 and the first insulating film 8. The first interlayer insulating film 12 is formed so as to fill in an area surrounded by the inner wall surfaces of the STI 2, of the insulating films 3 stacked thereon, and of mask films 4 stacked thereon, namely, in a pillar trench forming area A. A second interlayer insulating film 20 is formed on surfaces of the mask films 4 and of the first interlayer insulating film 12. A stopper film 21 is provided so as to cover the second interlayer insulating film 20, and a third interlayer insulating film 24 is provided so as to cover the stopper film 21.

A gate-lifting wire 42A is disposed on a surface of the third interlayer insulating film 24. The gate-lifting wire 42A is connected to the feeding gate electrode 11b through a gate metal contact plug (conductive plug) 41A, which penetrates the third interlayer insulating film 24, the stopper film 21, the second interlayer insulating film 20, and the first interlayer insulating film 12.

The conductive plug 41A is formed in the area where the conductive plug 41A partially overlaps the dummy pillar 6A. More specifically, the conductive plug 41A is formed in the area where the conductive plug 41A partially overlaps the insulating layer pillar 6A₂. The mask film 4 is disposed over the dummy pillar 6A, and the conductive plug 41A is connected to an upper end portion of the feeding gate electrode 11b positioned at the side face of the mask film 4. In conduction with the dummy pillar 6A, the mask film 4 provided over the dummy pillar 6A serves as a protruding layer which increases the height of the feeding gate electrode 11b and which shortens the distance between the feeding gate electrode 11b and the gate-lifting wire 42A provided above the feeding gate electrode 11b.

First and second metal wires 33 and 34 are disposed on the third interlayer insulating film 24. Silicon plugs 19 and source metal contact plugs (conductive plugs) 30A are disposed between the first metal wire 33 and the pillar upper diffused layers 16. The silicon plugs 19 are enclosed with the first interlayer insulating film 24 and the transistor gate electrodes 11a. Each conductive plug 30A penetrates the third interlayer insulating film 24, the stopper film 21, and the second interlayer insulating film 20. Accordingly, the first metal wire 33 is connected to the pillar upper diffused layers (the source diffused layers) 16 of the respective silicon pillars 5A through the silicon plugs 19 and the conductive plugs 30A. Hence, the respective unit transistors 50A share the pillar lower diffused layer 9 and constitute a single parallel transistor in which the respective pillar upper diffused layers are mutually connected by the first metal wire 33.

Each silicon plug 19 is formed by injecting (diffusing) impurities such as arsenic into silicon. In conjunction with the pillar upper diffused layers 16, the silicon plugs 19 configure a source section of the unit transistors 50A. Sidewall films 18 and insulating films 17 are disposed on the side faces of the silicon plugs 19. Hence, the silicon plugs 19 are electrically insulated from the transistor gate electrodes 11a by means of sidewall films 18 and the insulating films 17. A combination of the sidewall film 18 and the insulating film 17 is also called a second insulating film.

A drain metal contact plug (conductive plug) 31A is disposed between the second metal wire 34 and the pillar lower diffused layer 9. The conductive plug 31A penetrates the third interlayer insulating film 24, the stopper film 21, the second interlayer insulating film 20, and the first insulating film 8. Accordingly, the second metal wire 34 is connected to the pillar lower diffused layer (the drain diffused layer) 9 by means of the conductive plug 31A. The conductive plug 31A is disposed in the active region 39 at an opposed location to the dummy pillar 6A with respect to the silicon pillar group 5.

Referring now to a plan view of FIG. 1A, the semiconductor device according to this example is configured so that the active region 39 and a STI 2a serving as a part of the STI 2 are adjacently disposed in the pillar trench forming area A enclosed with the STI 2. Accordingly, among four side of the rectangular active region 39, three sides are bounded by the STI 2 and the remaining one side is bounded by the STI 2a. The silicon pillar group 5 comprising the first through the fifth silicon pillars 5A₁ to 5A₅ each having a rectangular cross section in the XY plane is provided in the active region 39. The first through the fifth silicon pillars 5A₁ to 5A₅ are arranged in the Y direction (the first direction) in a line with the space left therebetween. Each silicon pillar 5A forms the channel portion of each unit transistor 50A. In the active region 39, the unit transistor group 50 comprising the first through the fifth unit transistors 50A₁ to 50A₅ each having the silicon pillar 5A as the channel portion is disposed.

In the first example being illustrated, a single vertical transistor comprises the unit transistor group 50 serving as a cluster of the first through the fifth unit transistors 50A₁ to 50A₅. However, the number N of the unit transistors constituting the unit transistor group 50 is not limited to five. In addition, the number N of the unit transistors 50A is an integer which is not less than three.

Immediately above the silicon pillar group 5, the silicon plugs 19, the source metal contact plugs 30A, and the first metal wire 33 are disposed. The silicon pillar group 5, the silicon plugs 19, and the source metal contact plugs 30A are arranged within the same planar area to that they overlap with each other in the XY plane. The first metal wire 33 is disposed so as to extend in the Y direction.

The dummy pillar 6A having a rectangular shape in the XY plane is disposed so as to be adjacent to the third silicon pillar (the particular semiconductor pillar) 5A₃ which is positioned in a center of the silicon pillar group 5 serving as a cluster of the plurality of silicon pillars 5A₁ to 5A₅. The dummy pillar 6A is arranged at a boundary portion of the active region 39 and the STI 2a which are positioned in the pillar trench forming area A. Although a width in the Y direction of the dummy pillar 6A is equal to the width of each silicon pillar 5A, a width in the X direction thereof is especially not limited. Above the dummy pillar 6A, the conductive plug 41A having the rectangular shape in the XY plane is disposed. Although the conductive plug 41A is disposed at the position where the conductive plug 41A partially overlaps to the insulating layer pillar 6A₂ in the XY plane, the conductive plug 41A slightly extends off the insulating layer pillar 6A₂ outwards in the X direction and the Y direction. In addition, at the extended-off portion, the conductive plug 41A is connected to the feeding gate electrode 11b provided in the side face of the dummy pillar 6A.

Although, in FIG. 1A, the five silicon pillars constituting the silicon pillar group 5 are disposed in the first direction (the Y direction), the conductive plug 31A, the silicon pillar group 5, and the dummy pillar 6A are arranged in the second direction (the X direction) orthogonal to the first direction, and the drain wire 34, the source wire 33, and the gate-lifting wire 42A are disposed so as to overlap to them, arrangements of the respective components may be not limited to them. For example, if the silicon pillar group 5 comprises the even number of silicon pillars 5A extending in the Y direction, the dummy pillar 6A may be adjacent to a connection portion of the silicon pillars 5A that is positioned at a center of the silicon pillar group 5.

Now, description will be made as regards a method of manufacturing the semiconductor device according to the first example in detail.

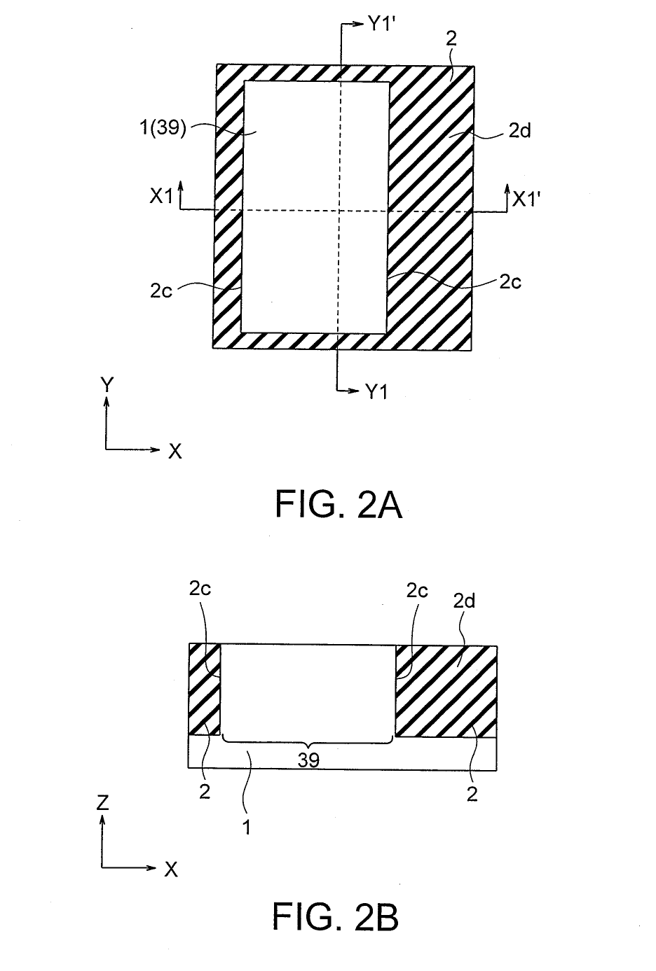

FIGS. 2-14 are process diagrams for use in describing the method of manufacturing the semiconductor device according to the first example. In each (Fig. O) of FIGS. 2-14, Fig. OA is a plan view of the semiconductor device in each manufacturing process, Fig. OB is a cross-sectional view taken on line X1-X1′ of Fig. OA, and Fig. OC is a cross-sectional view taken on line Y1-Y1′ of Fig. OA. In addition, the description of each manufacturing process will be mainly carried out using the cross-sectional view of Fig. OB, as appropriate, supplementary description of Fig. OB will be carried out by adding the drawings of Fig. OA and Fig. OC. Furthermore, in Fig. OA, components serving as foundations of the top layer are depicted at broken lines in order to make arrangement conditions of the respective components clear.

First, as shown in FIGS. 2A and 2B, a trench 2c is formed in a p-type silicon substrate 1 using a photography method and a dry etching method.

Subsequently, an element separation insulating film 2d comprising a silicon oxide film or a silicon nitride film is deposited to the entire surface of the silicon substrate 1 so as to fill in the trench 2c by a chemical vapor deposition (CVD) method. Thereafter, undesired element separation insulating film 2d on the silicon substrate 1 is removed by a chemical mechanical polishing (CMP) method so that the silicon nitride film is left in the trench 2c to form an STI 2 serving as an element isolation region. Herein, the silicon substrate 1 enclosed by the STI 2 becomes an active region 39.

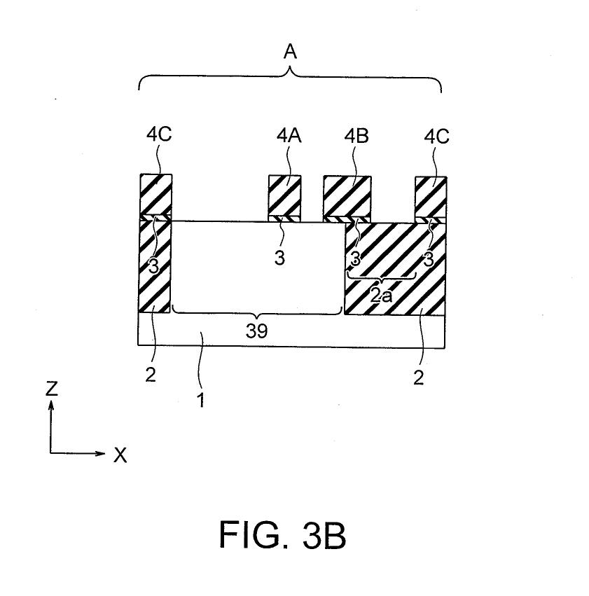

Next, as shown in FIG. 3B, an insulating film 3 serving as a silicon oxide film of 2 nm in thickness is formed on the silicon substrate 1 by the CVD method, and then mask films 4 each serving as a silicon nitride film of 120 nm in thickness are formed on the insulating film 3.

Next, the insulating film 3 and the mask films 4 are patterned using a photolithography process and a dry etching process. Hence a mask film 4C for delimiting the pillar trench forming area A is formed. In addition, mask films 4A for the respective silicon pillars 5A and a mask film 4B for the dummy pillar 6A are simultaneously formed. In an area in the pillar trench forming area A except that the respective mask films, a surface of the silicon substrate 1 constituting the active region 39 and a surface of a STI 2a serving as a part of the STI 2 are exposed. The mask films 4A are formed in the first direction (the Y direction) in alignment. The mask film 4B is formed so as to be adjacent to the mask film 4A which is positioned in an intermediate portion exclusive of both end portions of the mask films 4A arranging in the first direction (the Y direction). In addition, the mask film 4C is formed in a position which extends over the active region 39 and the STI 2a.

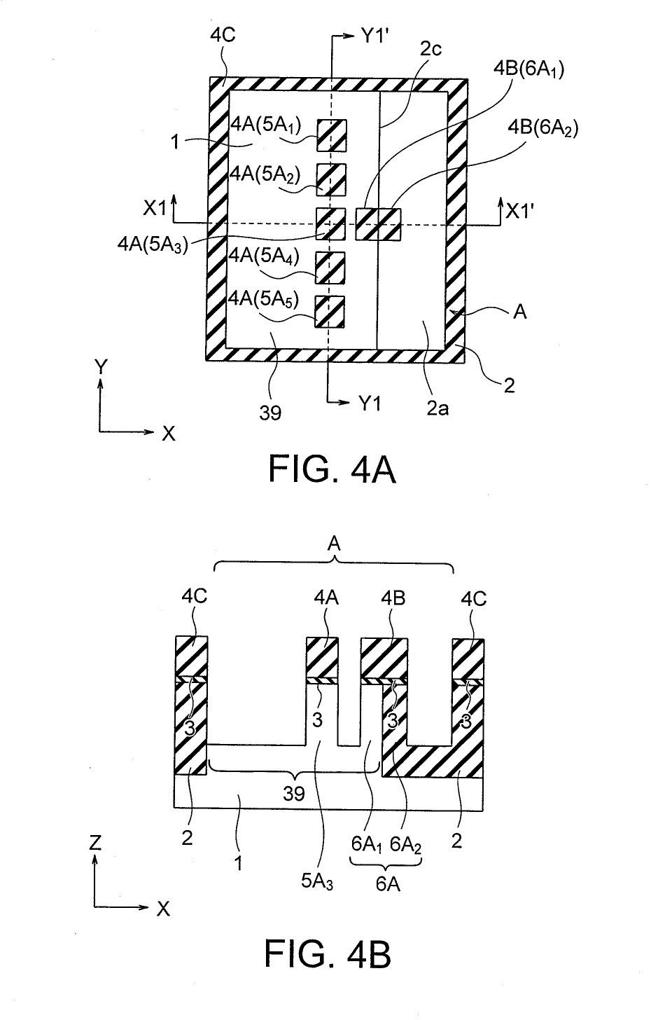

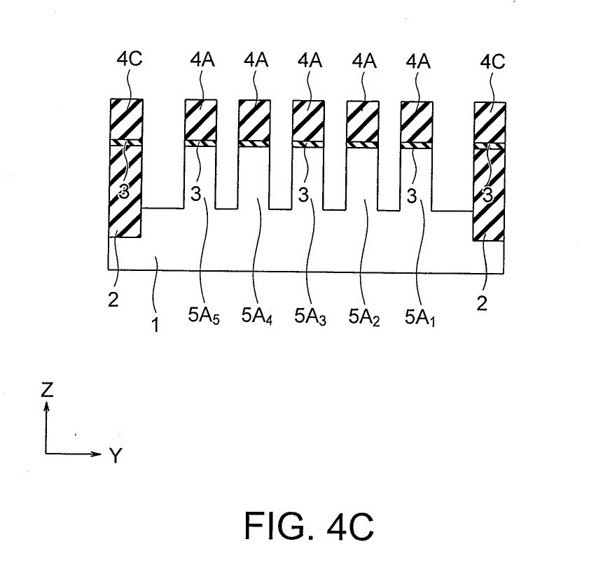

Next, as shown in FIGS. 4A, 4B, and 4C, the active region 39 and the STI 2a having the exposed surfaces are etched using the mask films 4A, 4B, and 4C as masks to form the five silicon pillars 5A₁ to 5A₅ and the dummy pillar 6A each having a depth of approximately 150 nm. The dummy pillar 6A comprises a composite pillar into which a dummy silicon pillar 6A₁ formed in the active region 39 side and an insulating layer pillar 6A₂ formed in the STI 2a side are incorporated.

Specifically speaking, the five silicon pillars 5A₁ to 5A₅ each constituting a unit transistor are arranged in the active region 39 in the first direction, and the interval between the respective silicon pillars 5A is made double or less the film thickness of each gate electrode which will be formed later. Likewise, the dummy pillar 6A is arranged in the second direction perpendicular to the first direction so as to be adjacent to the third silicon pillar (the particular semiconductor pillar) 5A₃ with the interval of double or less the film thickness of each gate electrode. The respective silicon pillars 5A have the same size in plane. A thickness (i.e., the size of the cross-section in a plane parallel to the silicon substrate 1) of each silicon pillar 5A constituting the channel portion of the transistor is a value which allows full depletion. Although a width in the first direction of the dummy pillar 6A is equal to the width of the silicon pillar 5A, a width in the second direction thereof can be different from that of the silicon pillar 5A.

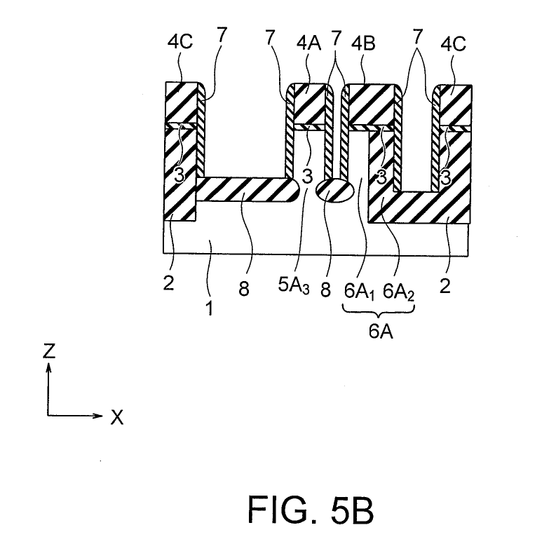

Subsequently, as shown in FIG. 5B, after a nitride film of 5 nm in thickness is deposited by the CVD method on the entire surface, the entire surface is etched back to form sidewall films 7 on the side faces of the respective silicon pillars 5A, of the dummy pillar 6A, and of the mask films 4A, 4B, and 4C. At this time, a sidewall film 7 is also formed on the side face of the STI 2.

Next, by the thermal oxidation method, a first insulating firm 8 serving as a silicon oxide film of 30 nm in thickness is formed on the surface of the silicon substrate 1 that is exposed at the bottom surface of the active region 39. At this time, the side faces of the respective silicon pillars 5A and the dummy pillar 6A are not formed with the silicon oxide films because the sidewall films 7 are formed thereon and the mask films 4 are formed on the upper surfaces thereof.

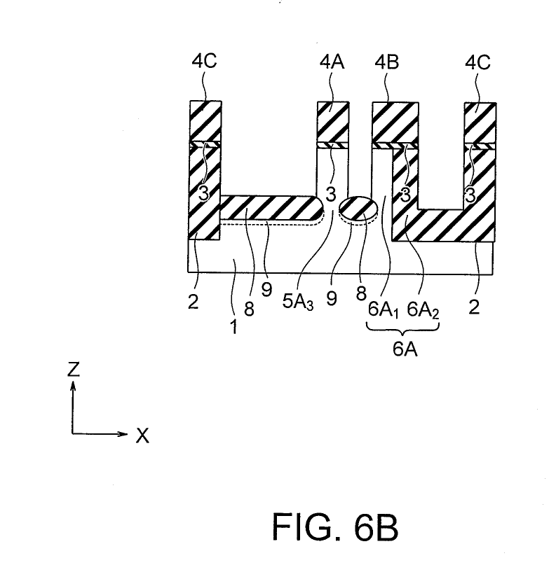

Subsequently, as shown in FIG. 6B, by ion implantation, an n-type impurity such as arsenic is introduces in the silicon substrate 1 which is positioned under the first insulating film 8 to form a pillar lower diffused layer 9 which comes into contact with the first insulating film 8. Herein, the pillar lower diffused layer 9 is shared in the five silicon pillars 5A₁ to 5A₅.

At this time, inasmuch as the side faces of the respective silicon pillars 5A for forming the transistors are protected with the sidewall films 7, it is possible to prevent diffusion ions from implanting into the pillar portions. If the sidewall films 7 are absent, serendipitous impurities are implanted into the pillar portions serving as channels, and it is therefore difficult to control threshold voltages of the transistors.

Subsequently, by the dry etching method or a wet etching method, the sidewall films 7 are removed.

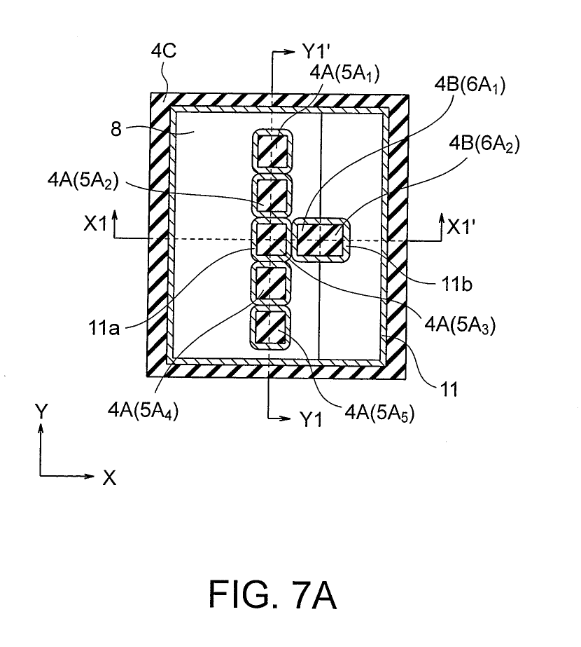

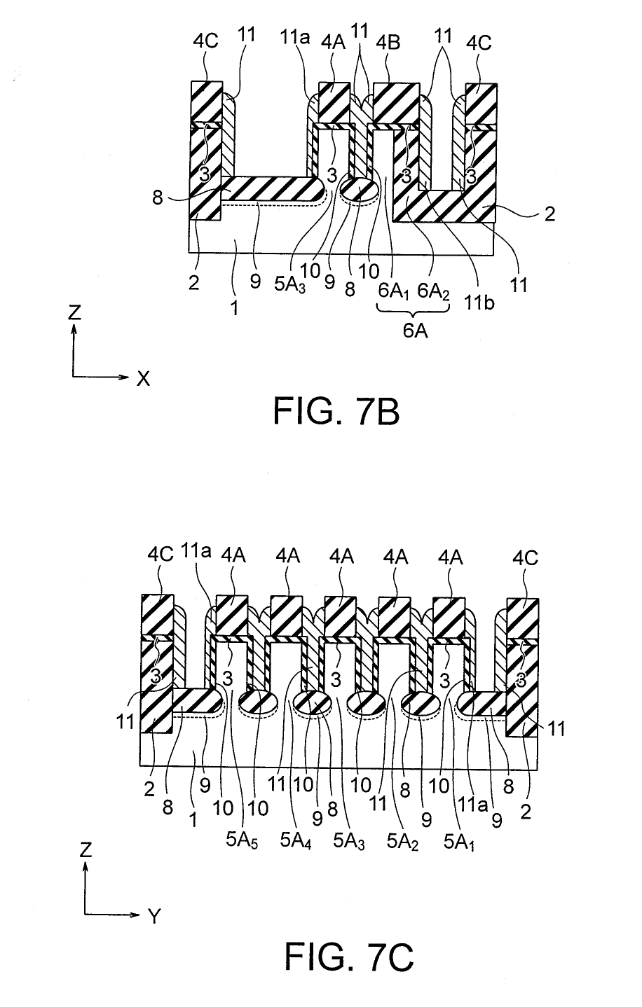

Subsequently, as shown in FIGS. 7A, 7B, and 7C, by the thermal oxidation method, gate insulating films 10 serving as silicon oxide films each having a thickness of 3 nm are formed on the side faces of the respective silicon pillars 5A and the dummy silicon pillar 6A₁.

Next, a polycrystalline silicon film of 20 nm in thickness for forming gate electrodes is deposited over the entire surface of the silicon substrate 1 by the CVD method, and the entire surface is etched back by the dry etching method to form the transistor gate electrodes 11a over the side faces of the respective silicon pillars 5A. At the same time, the feeding gate electrode 11b is formed over the side face of the dummy pillar 6A. Deposited by the CVD method using thermal cracking such as a silane (SiH4) gas, the polycrystalline silicon film has an extremely good stripping coatability because it is deposited at a surface reaction rate-determining. That is, it is possible to form it at the same film thickness on the plane or the side faces of the silicon pillars.

As a substitute for the polycrystalline silicon film, an amorphous silicon film may be formed. The amorphous silicon film has a remarkably flat deposited surface as compared with a case of forming with the polycrystalline silicon film because it does not have crystalline and it is advantageous in that it is possible to control a shape of an upper surface of the gate electrodes on etching back because it does not have asperities on the surface thereof. It is necessary to introduce the impurity to make the gate electrodes exhibit conductivity in the polycrystalline silicon film or in the amorphous silicon film.

Introduce of the impurity is carried out by concurrently supplying a phosphine (PH3) gas in addition to the silane gas as a material gas on depositing by the CVD method. Therefore, it is possible to form a silicon film in which phosphorus is contained in the deposited film. Although the silicon film formed at a state of polycrystalline exhibits conductivity at a formed step because the activation of phosphorus progresses during deposition, the silicon film formed at a state of amorphous is subjected to heat treatment of the activation of impurity as a process after forming it because the activation of phosphorus is not reached therein.

The condition for depositing the silicon film at the above-mentioned state of polycrystalline or amorphous has a dependence on a deposition temperature. More specifically, in a case of forming the polycrystalline silicon film, the deposition may be made at temperature between 570° C. and 640° C., both inclusive. This is because a reaction rate is high if the temperature is more than 640° C., and it is impossible to maintain a film thickness uniformity in a surface of the substrate and between substrates. In addition, in a case of forming the amorphous silicon film, the deposition may be made at temperature between 540° C. and 500° C., both inclusive. This is because a deposition rate remarkably reduces if the temperature is less than 500° C., and it has no practical applicability.

When the gate electrodes 11 are formed on the side faces of the respective silicon pillars 5A and of the dummy pillar 6A, a gage electrode 11 is also formed on the side face of the STI 2. As shown in FIGS. 7B and 7C, inasmuch as each of the interval between the particular semiconductor pillar 5A₃ and the dummy pillar 6A and the interval between the adjacent silicon pillars 5A is double or less the film thickness of each gate electrode 11, the gap between the particular semiconductor pillar 5A₃ and the dummy pillar 6A and the gapes between the adjacent silicon pillars 5A are completely buried by the gate electrodes 11. Accordingly, the transistor gate electrodes 11a in the side faces of the first through the fifth silicon pillars 5A₁ to 5A₅ and the feeding gate electrode 11b in the side face of the dummy pillar 6A are connected to each other so as to become integrated into a single gate electrode.

In the manner which is described above, the first example uses the method of forming the polycrystalline silicon film serving as the material of the gate electrodes on the entire surface in a state where the silicon pillars are formed so as to thrust out the silicon substrate 1 upwards, of etching buck by the anisotropic dry etching method, and of forming the gate electrodes 11 comprising the polycrystalline silicon film on the side faces of the silicon pillars. In etching back, formed on the upper surfaces of the respective silicon pillars 5A and on the horizontal surface which is composed at the bottom surfaces of circumferences of the respective silicon pillars 5A, the polycrystalline silicon film is etched to disappear. That is, the etching back uses that the film thickness of the polycrystalline silicon film formed on the plane is thinner than film thickness of the polycrystalline silicon film in a depth direction (the thickness of the silicon pillars in a height direction) that is formed on the side faces of the silicon pillars. Accordingly, in order to form the gate electrodes 11 by the etching back, the existence of the silicon pillars in themselves is absolutely necessary.

If the mask is not normally formed in the process for forming the silicon pillars and eventually the silicon pillars are not formed, an area thereof becomes merely a plane. And, the polycrystalline silicon film formed thereon is etched to disappear on etching back and the gate electrodes 11 are not formed. As a result, it causes a problem where connection of the gate electrodes 11 between the adjacent silicon pillars cannot be performed.

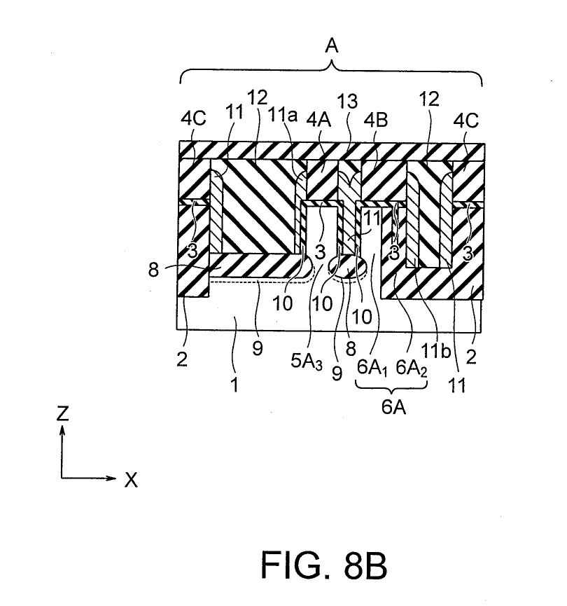

Subsequently, as shown in FIG. 8B, a first interlayer insulating film 12 serving as a silicon oxide film is formed by the CVD method so as to cover the respective silicon pillars 5A and the dummy pillar 6A to bury concave portions formed in the pillar trench forming area A.

Next, by the CMP method, the first interlayer insulting film 12 is flattened so as to expose upper surfaces of the mask films 4A, 4B, and 4C, and then, by the CVD method, a mask film 13 serving as a silicon oxide film of 10 nm in thickness is deposited.

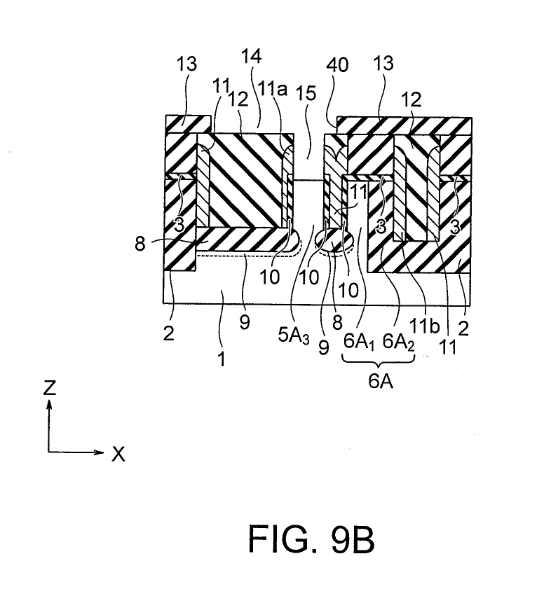

Subsequently, as shown in FIG. 9B, a part of the mask film 13 is removed using the photolithography method and the etching method to form a first opening portion 14. A pattern 40 of the removed mask film 13 is, as shown in FIG. 1A, a pattern which is lied in the active region 39 and which bores an area including the mask films 4A on the respective silicon pillars 5A. Therefore, in the first opening portion 14 in which the mask film 13 is removed, the upper surfaces of the mask films 4A positioned on the respective silicon pillars 5A are exposed.

Subsequently, the exposed mask films 4A are selectively removed by the wet etching and the insulating film 3 is removed to form second opening portions 15 over the respective silicon pillars 5A. The second opening portions 15 have bottom surfaces in which the upper surfaces of the respective silicon pillars 5A are exposed and have side faces in which parts of the transistor gate electrodes 11a are exposed.

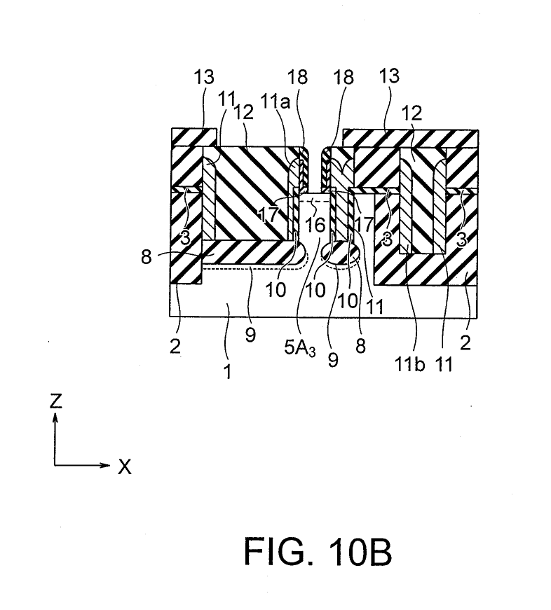

Next, as shown in FIG. 10B, by the thermal oxidation method, insulating films 17 serving as silicon oxide films are formed on inner walls of the second opening portions 15.

Subsequently, n-type impurities such as phosphorus or arsenic are ion-injected into the upper portions of the respective silicon pillars 5A through the second opening portions 15 to form pillar upper diffused layers 16. In addition, a silicon nitride film of 10 nm in thickness is deposited in the entire surface by the CVD method, and thereafter an etch-back process is performed by the dry etching method to form sidewall films 18 in inner walls of the second opening portions 15. In forming the sidewall films 18, the insulting films 17 formed on the top faces of the respective silicon pillars 5A are removed to expose the top faces of the respective silicon pillars 5A. In this event, the insulating films 17 remain under the sidewall films 18 and on exposed surfaces of the gate electrodes 11 in the second opening portions 15. The sidewall films 18 play a role in ensuring to insulate the transistor gate electrodes 11a from silicon plugs which will be formed later.

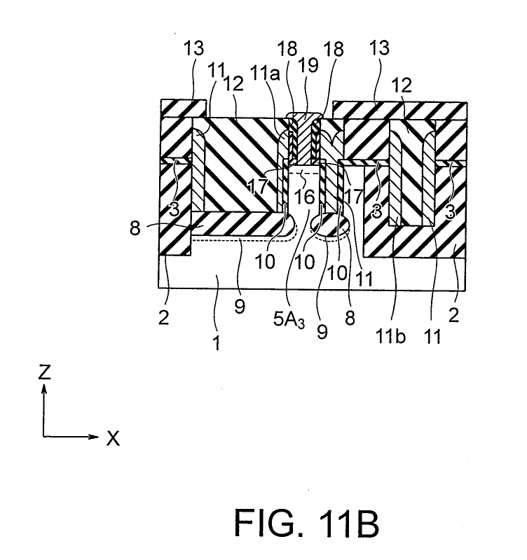

Subsequently, as shown in FIG. 11B, using a selective epitaxial growth method, the silicon plugs depicted at 19 are grown using the top faces of the respective silicon pillars 5A each comprising a single crystal as seeds so as to bury the second opening portions 15. Thereafter, when an N-channel transistor is to be formed, ions such as arsenic ions are injected to make the silicon plugs 19 n-type conductors, thereby the silicon plugs 19 electrically connecting the pillar upper diffused layers 16 formed on the upper portions of the respective silicon pillars 5A.

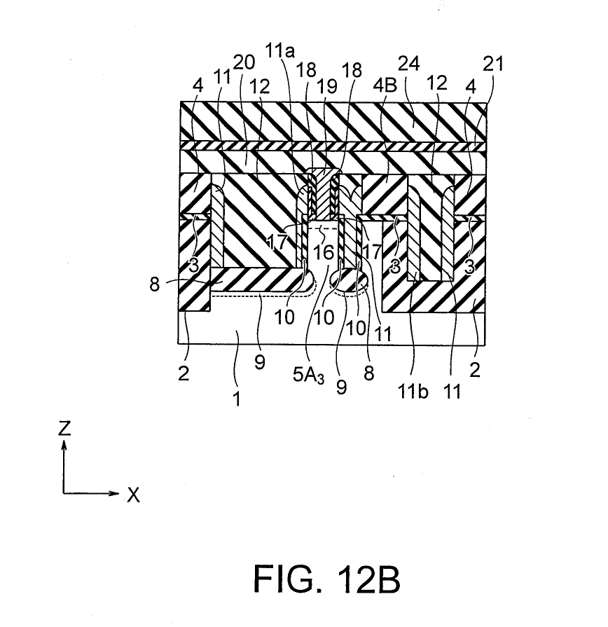

Subsequently, as shown in FIG. 12B, a second interlayer insulating film 20 serving as a silicon oxide film is formed so as to bury the first opening portion 14 by the CVD method. The mask film 13 comprising the silicon oxide film is absorbed and united to the second interlayer insulating film 20.

Thereafter, a stopper film 21 serving as a silicon nitride film of 20 nm in thickness is deposited by the CVD method.

Then, a third interlayer insulting film 24 serving as a silicon oxide film of 150 nm in thickness is deposited by the CDV method.

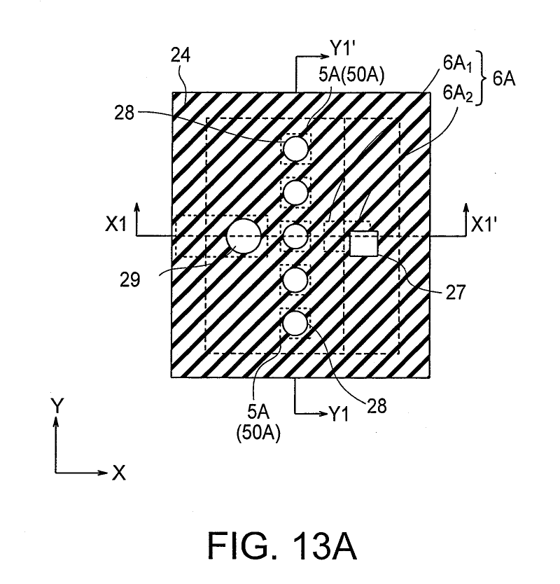

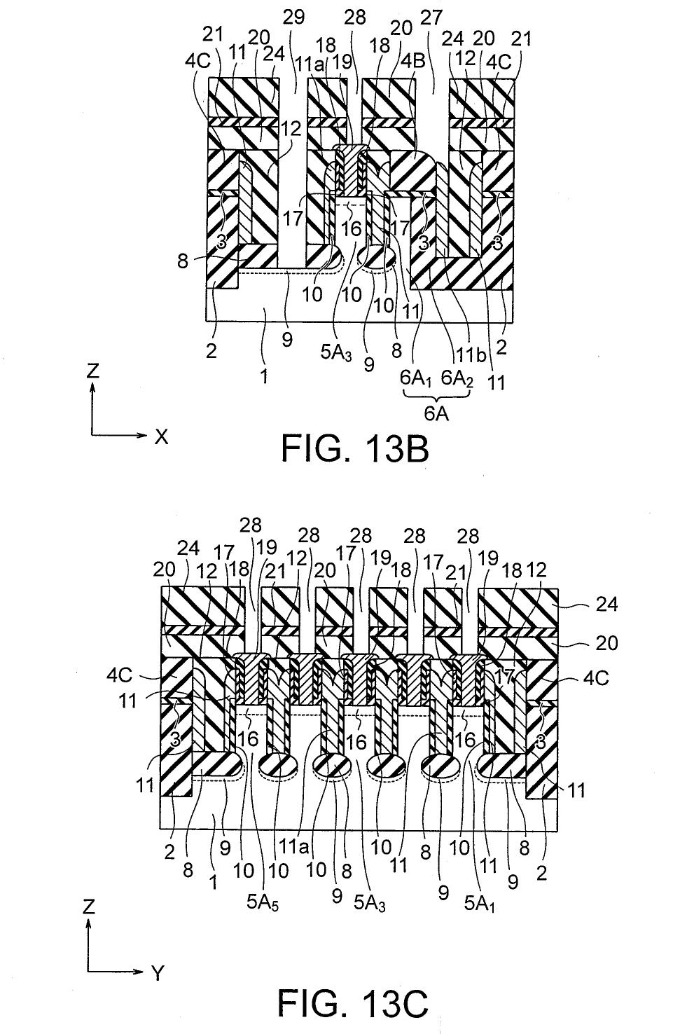

Next, as shown in FIGS. 13A, 13B, and 13C, using the photolithography method and the dry etching method, first through third contact holes 27 to 29 are formed. In forming the first through the third contact holes 27 to 29, it is necessary to dry-etch until forming of the deepest third contact hole 29 finishes. Consequently, the relatively shallow first and second contact holes 27 and 28 are added with excessive etching. Specifically, in the first contact hole 27 in which mating displacement in lithography easily occurs, the first interlayer insulating film 12 is excessively etched at a portion in which the mating displacement occurs. Under the circumstances, if the dummy pillar 6A comprises only the dummy silicon pillar 6A₁ which is positioned in the active region 39, by carrying out etching in the same depth of the third contact hole 29, the first contact hole 27 may penetrate the silicon substrate 1 positioned at the bottom surface of the active region 39. As a result, it cause problem such that the silicon substrate 1 shorts with a contact plug 41A which will be formed later, namely, the feeding gate electrode 11b shorts with the pillar lower diffused layer 9 via the contact plug 41A. However, in this example, the dummy pillar 6A comprises the composite pillar including the STI 2a, and the first contact hole 27 is formed at the STI 2a side. Inasmuch as the STI 2a is formed in depth by about 100 nm as compared with a depth of the third contact hole 29, it is possible to form the position of the bottom thereof in the STI 2a although the mating displacement portion is excessively etched, and it is possible to avoid contact with the silicon substrate 1. Accordingly, it is possible to prevent the feeding gate electrode 11b and the pillar lower diffused layer 9 from short-circuiting. In this example, the reason that the dummy pillar 6A for the gate feeding is formed by the composite pillar is for ensuring this advantage.

In addition, in order to improve controllability of the dry etching, it uses a method of performing the etching of the stopper film 21 and the etching of the first interlayer insulating film 12 in stages by temporarily stopping the etching at the stopper film 21. In forming the first contact hole 27, inasmuch as the upper face of the dummy pillar 6A is protected with the mask film 4B remaining, the dummy pillar 6A is not etched. Inasmuch as the dummy pillar 6A is formed at the position displaced from a center of the dummy pillar 6A, at the bottom portion thereof, the mask film 4B formed over the dummy pillar 6A and a part of the feeding gate electrode 11b formed on the side face of the dummy pillar 6A are exposed.

Furthermore, the second contact holes 28 have bottom portions at which at least parts of the contact plugs 19 are exposed, and the third contact hole 29 has a bottom portion at which a part of the pillar lower diffused layer 9 is exposed.

The first through the third contact holes 27 to 29 may be formed at the same time or may be formed individually.

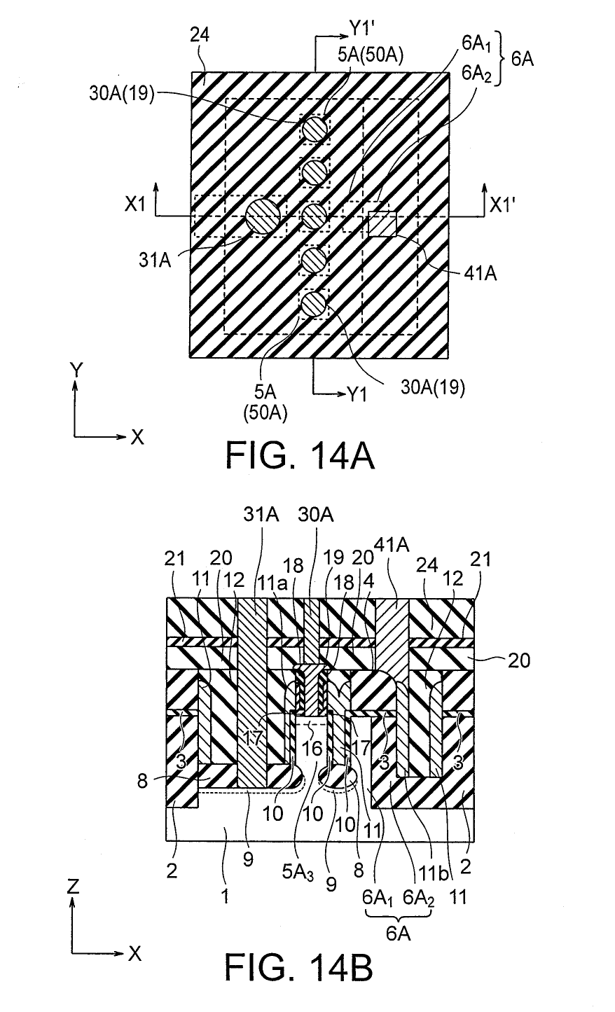

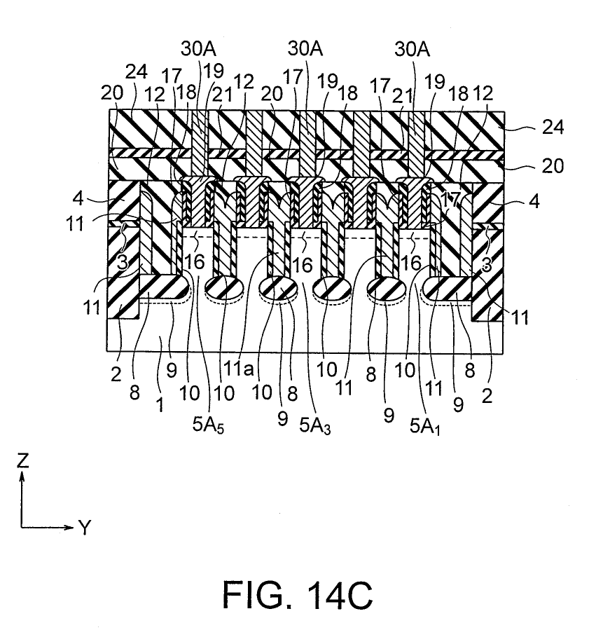

Next, as shown in FIGS. 14A, 14B, and 14C, the first through the third contact holes 27 to 29 are filled by depositing a metal film made from tungsten (W), titanium nitride (TiN), and titanium (Ti) so as to cover the third interlayer insulating film 24.

Subsequently, by using the CMP method, the metal film on the third interlayer insulating film 24 is removed to form five source metal contact plugs 30A for the silicon plugs 19, a drain metal contact plug 31A for the pillar lower diffused layer 9, and a gate metal contact plug 41A for the feeding gate electrodes 11b.

Next, as shown in FIGS. 1A, 1B, and 1C, a first metal wire (a source wire) 33, a second metal wire (a drain wire) 34, and a gate-lifting wire (a gate wire) 42A, each of which is made from tungsten (W) and tungsten nitride (WN), are formed by a spatter method. In this event, the gate metal contact plug 41A is connected to the gate-lifting wire 42A. In addition, connected to the pillar lower diffused layer 9, the drain metal contact plug 31A is connected to the second metal wire 34. Furthermore, connected to the pillar upper diffused layers 16 formed on the five silicon pillars 5A₁ to 5A₅, the five source metal contact plugs 30A are connected to the first metal wire 33. Thus, a single vertical transistor in which the five unit transistors 50A are connected in parallel is formed.

In accordance with the semiconductor device of the first example described above, the following advantages are obtained.

(1) The dummy pillar 6A is arranged so as to be adjacent to the particular semiconductor pillar positioned to the central portion of the silicon pillar group (the semiconductor pillar group) 5 comprising the plurality of silicon pillars (semiconductor pillars) 5A. It is therefore possible to suppress a fault of the unit transistors comprising normal silicon pillars with a minimum although a part of the plurality of silicon pillars 5A constituting the silicon pillar group 5 is abnormally formed so that the gate electrodes 11 are broken.

More specifically, it will be assumed in FIG. 1A that the second silicon pillar 5A₂ composing one side of the silicon pillar group 5 abutted against the third silicon pillar 5A₃ adjacent to the dummy pillar 6A is abnormally formed so that the gate electrode 11 is broken. In this event, the second unit transistor 50A₂ comprising the second silicon pillar 5A₂ abnormally formed and the first unit transistor 50A₁ adjacent to the second silicon pillar 5A₂ go out of order so that operations become impossible. However, three unit transistors, namely, third, fourth, and fifth unit transistors 50A₃, 50A₄, and 50A₅ composing the central portion and other side of the silicon pillar group 5 do not go out order to normally operate.

In compassion with this, if the dummy pillar 6A is arranged to as to be adjacent to the first silicon pillar 5A₁ and when the second silicon pillar 5A₂ is abnormally formed in the manner as described above, only the first unit transistor 50A₁ normally operates.

(2) Inasmuch as the interval between adjacent silicon pillars 5A and the interval between the particular silicon pillar 5A₃ and the dummy pillar 6A are made double or less the thickness of each gate electrode 11, the gate electrodes 11 formed on the side faces of the respective silicon pillars 5A and of the dummy pillar 6A make contact with each other, and the gate electrodes 11 are formed over the entire side faces of the respective silicon pillars 5A in a height direction. Therefore, although gate electrodes 11 formed in unnecessary areas are removed by an etch-back process, the disconnection of the gate electrodes 11 does not arise in the gaps between the respective silicon pillars 5A and the dummy pillar 6A, and these gate electrodes 11 serve as a single contiguous gate electrode. Moreover, reducing the interval between the respective silicon pillars 5A and the dummy pillar 6A contributes to the miniaturization of the semiconductor device.

(3) Inasmuch as the protrusion layer (the dummy pillar 6A, the mask film 4B) for shoring up the height of the feeding gate electrode 11b is formed, the aspect ratio of the gate metal contact plug 41A for connecting the gate electrodes 11 with the gate-lifting wire 42A can be reduced, so that it is possible to easily deal with the refinement of the semiconductor device. In addition, inasmuch as the dummy pillar 6A is formed by the composite pillar into which the dummy silicon pillar 6A₁ and the insulating layer pillar 6A₂ make contact with each other to be incorporated and the gate metal contact plug 41A is formed at the insulating layer pillar 6A₂ side, it is possible to avoid a short circuit between the gate electrodes 11 and the pillar lower diffused layer 9 arising from pattern displacement on forming the first contact hole 27 by etching.

### Example 2

Referring now to Figures, a second example of this invention will be described. Herein, configuration of the figures is similar to those of the first example. In addition, the description of contents having in common to the first example is omitted and only differences in the second example will be described.

In the first example, the unit transistor group 50 comprising the plurality of unit transistors 50A₁ to 50A₅ is configured to use as a single parallel transistor. Accordingly, the first example has structure required so that the conductive plug 31A is provided for feeding to the pillar lower diffused layer 9 which is in common to the unit transistor group 50.

The second example describes as regards configuration in which the conductive plug 31A it self is replaced with a parallel transistor. It becomes the configuration of a serial/parallel transistor in which two parallel transistors are connected in series with the pillar lower diffused layer in common.

Specifically speaking, it becomes the configuration so that two parallel transistors of the first example are symmetric about a line and are arranged in the same active region, the pillar lower diffused layer is in common, and the pillar upper diffused layers are connected to different wires, respectively.

Although the description will proceed to an example using two parallel transistors in the following description, the present invention is not limited to this, and it may make a serial/parallel transistor comprising a lot of transistors by arranging transistors having the same structure in a plurality of active regions and connecting them with wires.

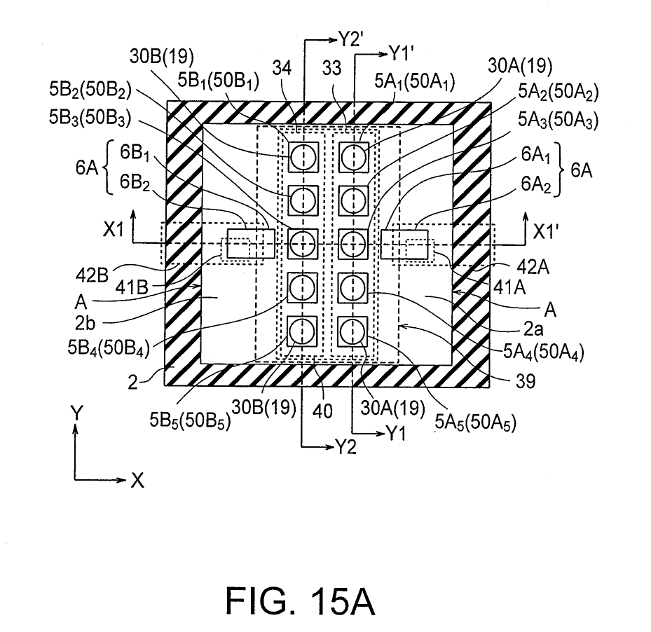

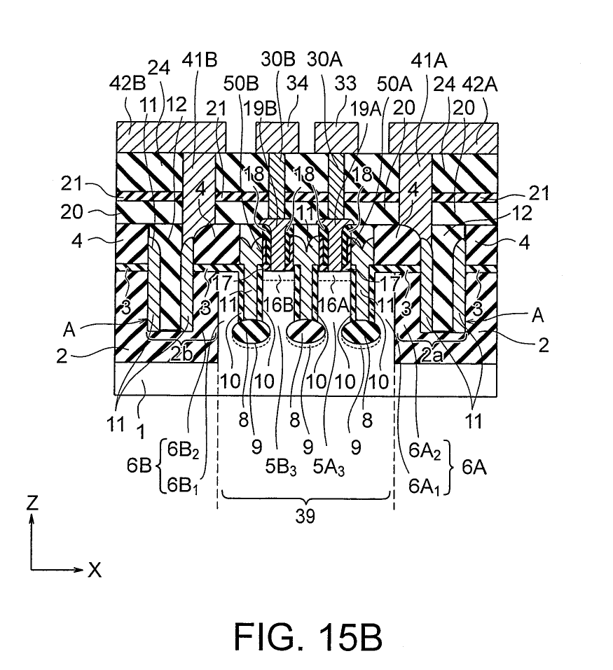

FIGS. 15A and 15B are schematic views showing a configuration of a semiconductor device according to the second example of this invention. FIG. 15A is a plan view of the semiconductor device the second example. FIG. 15B is a cross-sectional view taken on line X1-X1′ of FIG. 15A. However, in FIG. 15A, in order to define a layout condition of components, interlayer insulating films and wires positioned on contact plugs are put into a transmittance state and only in outline thereof is described. In addition, the individual configurations other than description below are similar to those of the first example and therefore are omitted.

Referring now to FIG. 15A, on the silicon substrate 1, the rectangular active region 39 surrounded by the SRI 2 is disposed. Two opposite sides of the active region 39 in the X direction are widen to the STI 2 side at positions at which the rectangular pillar trench forming area A has two sides. Accordingly, the active region 39 is disposed at a center in the pillar trench forming area A in the X direction and the two sides of the active region 39 in the X direction make contact with a STI 2a and a STI 2b serving as parts of the STI 2, respectively.

Ten silicon pillars 5′ each having a rectangular cross section in the XY plane are provided around the center of the active region 39. The ten silicon pillars 5′ are divined into a first silicon pillar group (a first semiconductor pillar group) 5a comprising first through fifth silicon pillars (semiconductor pillars) 5A₁ to 5A₅ and a second silicon pillar group (a second semiconductor pillar group) 5b comprising sixth through tenth silicon pillars (semiconductor pillars) 5B₁ to 5B₅. A first dummy pillar 6A corresponding to the first silicon pillar group 5a is arranged so as to be adjacent to a particular silicon pillar 5A₃ and is disposed at a position extending over the active region 39 and the STI 2a. In addition, a second dummy pillar 6B corresponding to the second silicon pillar group 5b is arranged so as to be adjacent to a particular silicon pillar 5B₃ and is disposed at a position extending over the active region 39 and the STI 2b. The interval between the first silicon pillar group 5a and the second silicon pillar group 5b, each of which is arranged in the Y direction (the first direction) in a line, is made double or less the thickness of each gate electrode 11. A position relationship between individual silicon pillars and a position relationship between the silicon pillar and the dummy pillar are similar to those of the first example. Accordingly, the gate electrodes 11 are arranged so as to connect all of the first dummy pillar 6A, the first silicon pillar group 5A, the second silicon pillar group 5B, and the second dummy pillar 6B. In addition, similar to the first dummy pillar 6A, the second dummy pillar 6B also comprises a second composite pillar into which a second dummy silicon pillar 6B₁ formed in the active region 39 side and a second insulating layer pillar 6B₂ formed in the STI 2 side are incorporated.

In the active region 39 surrounded by the STI 2, ten unit transistors 50 each having the silicon pillar 5′ as the channel portion are disposed. Herein, the ten unit transistors 50 are distinguished as first through fifth unit transistors 50A₁ to 50A₅ corresponding to the first through the fifth silicon pillars 5A₁ to 5A₅ and as sixth through tenth unit transistors 50B₁ to 50B₅ corresponding to the sixth through the tenth silicon pillars 5B₁ to 5B₅.

Accordingly, a first unit transistor group 50A comprises the first through the fifth unit transistors 50A₁ to 50A₅ while a second unit transistor group 50B comprises the sixth through the tenth unit transistors 50B₁ to 50B₅. In addition, the number N of the unit transistors constituting each unit transistor group is not limited to five and it may be three or more. The transistor of this example comprises a serial/parallel transistor in which the first unit transistor group 50A constituting a first parallel transistor and the second unit transistor group 50b constituting a second parallel transistor are connected in series.

More specifically, the semiconductor device according to the second example comprises:

the first semiconductor pillar group (5a) comprising first through N-th semiconductor pillars (5A₁ to 5A₅) which are formed in the first direction (Y) with a space left therebetween, where N represents a positive integer which is not less than three;

the second semiconductor pillar group (5b) adjacent to the first semiconductor pillar group (5a), the second semiconductor pillar group (5b) comprising (N+1)-th through 2N-th semiconductor pillars (5B₁ to 5B₅) which are formed in the first direction (Y) with a space left therebetween;

the first dummy pillar (6A) disposed near the first particular semiconductor pillar (5A₃) in the first semiconductor pillar group (5a) in a second direction (X) perpendicular to the first direction (Y), the first particular semiconductor pillar (5A₃) being any one of the second through the (N−1)-th semiconductor pillars (5A₂ to 5A₄) which are positioned in an intermediate portion exclusive of the first and the N-th semiconductor pillars (5A₁, 5A₅);

the second dumpy pillar (6B) disposed near the second particular semiconductor pillar (5B₃) in the second semiconductor pillar group (5b) in the second direction (X) at an opposite side of the first dummy pillar (6A), the second particular semiconductor pillar (5B₃) being any one of the (N+2)-th through the (2N−1)-th semiconductor pillars (5B₂ to 5B₄) which are positioned in an intermediate portion exclusive to the (N+1)-th and the 2N-th semiconductor pillars (5B₁, 5B₅);

the gate insulating films (10) which are formed on outer circumferential surfaces of the first through the 2N-th semiconductor pillars (5A₁ to 5A₅, 5B₁ to 5B₅) and which are formed on parts of outer circumferential surfaces of the first and the second dummy pillars (6A, 6B); and

the gate electrodes (11) formed over side faces of the first through the 2N-th semiconductor pillars (5A₁ to 5A₅, 5B₁ to 5B₅) and over side faces of the first and the second dumpy pillars (6A, 6B) via the gate insulating films (10) so as to fill gaps between the first through the 2N-th semiconductor pillars (5A₁ to 5A₅, 5B₁ to 5B₅), a gap between the first particular semiconductor pillar (5A₃) and the first dumpy pillar (6A), and a gap between the second particular semiconductor pillar (5B₃) and the second dummy pillar (6B).

Referring now to FIG. 15B, immediately above the first silicon pillar group 5a, a first silicon plug 19A, the first source metal contact plug 30A, and the first metal wire (the source wire) 33 are disposed. Likewise, immediately above the second silicon pillar group 5b, a second silicon plug 19B, a second source metal contact plug 30B, and the second metal wire (the drain wire) 34 are disposed. The first silicon pillar group 5a, the first silicon plug 19A, and the first source metal contact plug 30A are arranged so as to overlap to each other in the same region in the XY plane. Similarly, the second silicon pillar group 5b, the second silicon plug 19B, and the second source metal contact plug 30B are also arranged so as to overlap to each other in the same region in the XY plane. With this structure, the second metal wire (the drain wire) 34 functions also a wire for connecting the second silicon pillar group 5b comprising the five silicon pillars 5B₁ to 5B₅ in parallel.

In addition, the first unit transistor group 50A and the second unit transistor group 50B, each of which comprises a parallel transistor, are connected in series. Specifically, the first metal wire 33 is connected to the pillar lower diffused layer 9 via the first source metal contact plug 30A, the first silicon plug 19A, a first pillar upper diffused layer 16A, and the third silicon pillar 5A₃, and is further connected to the second metal wire 34 via the eighth silicon pillar 5B₃, a second pillar upper diffused layer 16B, the second silicon plug 19B, and the second source metal contact plug 30B.

Immediately above a second gate metal contact plug 41B, a second gate-lifting wire 42B is disposed. The second gate-lifting wire 42B is provided in a straight line in the XY plane and is disposed to extend in the X direction towards the other side so that it does not intersect to the second metal wire (the drain wire) 34. The second gate-lifting wire 42B has an end portion which is connected to the gate electrodes 11 of the second unit transistor group 50B via the second gate metal contact plug 41B.

Although the gate electrodes 11 are arranged so as to connect all of the first dummy pillar 6A, the first silicon pillar group 5a, the second silicon pillar group 5b, and the second dummy pillar 6B by configuring so that the interval between the first silicon pillar group 5a and the second silicon pillar group 5b, each of which is arranged in the first direction in proper arrangement, is made double or less the thickness of each gate electrode in the above description, this invention is not to limited to this. By way of illustration, if the interval between the first silicon pillar group 5a and the second silicon pillar group 5b is made more double the thickness of each gate electrode, it is possible to control the respective unit transistor groups individually in a state where first gate electrodes 11 of the first unit transistor group 50A and second gate electrodes 11 of the second unit transistor group 50B are separated.

In accordance with the semiconductor device of the second example described above, the following advantages are obtained.

(1) Inasmuch as the two parallel transistors, each of which has a structure described in the first example, are connected in series, it is possible to configure a more high-voltage serial/parallel transistor with be maintaining the advantage that it is possible to suppress a failure of unit transistors composed of normal silicon pillars at minimum although a part of plural silicon pillars constituting the silicon pillar group is abnormally formed to brake the gate electrodes.

(2) This example is configured that two vertical transistors where a pillar lower diffused layer is in common are connected in series. Inasmuch as the vertical transistor is not configured so that the pillar upper diffused layer and the pillar lower diffused layer have a symmetrical structure, a characteristic thereof is easily unevenness dependent on a direction of an electric current flowing through the channel. However, this example is configured that an electric current certainly flows through another transistor in an upward direction when an electric current flows through one transistor in a downward direction because the two vertical transistors are connected in series. Accordingly, the unevenness of the characteristic is cancelled and it is possible to obtain a stable characteristic.

(3) Inasmuch as the respective silicon pillar groups 5a and 5b, the first and the second metal wires 33 and 34 are connected by two conductive plugs: the silicon plugs 19A and 19B and the source metal contact plugs 30A and 30B, it is possible to reduce the aspect ratio of the respective conductive plugs as compared with a case where connection is made using one conductive plug. it is therefore possible to easily deal with the refinement of the semiconductor device. In particular in a case of the second example, inasmuch as a distance between each unit transistor group 50A, 50B and each metal wire is shored up by a height of the silicon pillars 5′, it is possible to make the conductive plug a smaller aspect ratio.

In addition, the second example is basically configured that more than the structure of the first example is laid out, and the individual structures are similar. Accordingly, a manufacturing method also can perform processes similar to those of the first example. As a result, the description of FIGS. 2 to 14 should be referred to as regards a method of manufacturing the semiconductor device according to the second example.

Although preferred examples of the present invention have been explained, the present invention is not limited to these examples. Various modifications can be made so long as they not depart from the gist of the present invention and they are included in a range of the present invention. For instance, although the foregoing examples employ the silicon substrate as an example of a semiconductor substrate, semiconductor pillars may be formed on a substrate other than a silicon substrate. Moreover, semiconductor pillars and a protruding layer may be formed by forming a semiconductor layer on an insulating substrate such as a glass substrate and by subsequently etching the semiconductor layer. Furthermore, the layouts of the metal contact plugs, the silicon plugs, and the wires are merely examples, and any modifications are possible in accordance with design requirements.

The whole or part of the exemplary embodiments disclosed above can be described as, but not limited to, the following supplementary notes.

### Supplementary Note 1

A method of manufacturing a semiconductor device, comprising:

forming a semiconductor pillar group and a dummy pillar on a substrate, the semiconductor pillar group comprising a plurality of semiconductor pillars formed in a first direction with a space left therebetween, the dummy pillar being disposed near a particular semiconductor pillar in the semiconductor pillar group in a second direction perpendicular to the first direction, the particular semiconductor pillar being any one of the semiconductor pillars which are positioned in an intermediate portion exclusive to both end portions;

forming a first insulating film on a surface of the substrate that is exposed about the respective semiconductor pillars;

injecting impurities in the substrate via the first insulating film to form a drain diffused layer under the first insulating film;

forming gate insulting films on outer circumferential surfaces of the plurality of semiconductor pillars and on a part of an outer circumferential surface of the dummy pillar; and

filling, via the gate insulating films, gaps between the plurality of semiconductor pillars and a gap between the particular semiconductor pillar and the dumpy pillar to form gate electrodes over side faces of the plurality of semiconductor pillars and over a side face of the dummy pillar.

### Supplementary Note 2

A method according to Supplementary note 1,wherein the particular semiconductor pillar comprises one of the plurality of semiconductor pillars that is located at a central portion of the semiconductor pillar group,

wherein the interval between adjacent semiconductor pillars is double or less the thickness of each gate electrode, the interval between the particular semiconductor pillar and the dumpy pillar is double or less the thickness of each gate electrode,

wherein the forming the gate electrodes comprising:

depositing a material for forming the gate electrodes on an entire surface of the substrate; and

etching back the entire surface to form the gate electrodes over the side faces of the plurality of semiconductor pillars and over the side face of the dumpy pillar.

### Supplementary Note 3

A method of manufacturing a semiconductor device, comprising:

forming first and semiconductor pillar groups and first and second dummy pillars on a substrate, the first semiconductor pillar group comprising first through N-th semiconductor pillars which are formed in a first direction with a space left therebetween, where N represents a positive integer which is not less than three, the second semiconductor pillar group being adjacent to the first semiconductor pillar group, the second semiconductor pillar group comprising (N+1)-th through 2N-th semiconductor pillars which are formed in the first direction with a space left therebetween, the first dummy pillar being disposed near a first particular semiconductor pillar in the first semiconductor pillar group in a second direction perpendicular to the first direction, the first particular semiconductor pillar being any one of the second through the (N−1)-th semiconductor pillars which are positioned in an intermediate portion exclusive of the first and the N-th semiconductor pillars, the second dumpy pillar being disposed near a second particular semiconductor pillar in the second semiconductor pillar group in the second direction at an opposite side of the first dummy pillar, the second particular semiconductor pillar being any one of the (N+2)-th through the (2N−1)-th semiconductor pillars which are positioned in an intermediate portion exclusive to the (N+1)-th and the 2N-th semiconductor pillars;

forming a first insulating film on a surface of the substrate that is exposed about the first through the 2N-th semiconductor pillars;

injecting impurities in the substrate via the first insulating film to form a drain diffused layer under the first insulating film;

forming gate insulting films on outer circumferential surfaces of the first through the 2N-th semiconductor pillars and on parts of outer circumferential surfaces of the first and the second dummy pillars; and

filling, via the gate insulating films, gaps between the first through the 2N-th semiconductor pillars, a gap between the first particular semiconductor pillar and the first dumpy pillar, and a gap between the second particular semiconductor pillar and the second dumpy pillar to form gate electrodes over side faces of the first through the 2N-th semiconductor pillars and over side faces of the first and the second dummy pillars.

### Supplementary Note 4

A method according to Supplementary note 3,

wherein the first particular semiconductor pillar comprises one of the second through the (N−1)-th semiconductor pillars that is located at a central portion of the first semiconductor pillar group,

wherein the second particular semiconductor pillar comprises one of the (N+2)-th through the (2N−1)-th semiconductor pillars that is located at a central portion of the second semiconductor pillar group,

wherein the interval between adjacent semiconductor pillars is double or less the thickness of each gate electrode, the interval between the first particular semiconductor pillar and the first dumpy pillar is double or less the thickness of each gate electrode, and the interval between the second particular semiconductor pillar and the second dumpy pillar is double or less the thickness of each gate electrode,

wherein the forming the gate electrodes comprising:

depositing a material for forming the gate electrodes on an entire surface of the substrate; and

etching back the entire surface to form the gate electrodes over the side faces of the first through the 2N-th semiconductor pillars and over the side faces of the first and the second dumpy pillars.

### Supplementary note 5

A method of manufacturing a semiconductor device, comprising:

forming first and semiconductor pillar groups and first and second dummy pillars on a substrate, the first semiconductor pillar group comprising first through N-th semiconductor pillars which are formed in a first direction with a space left therebetween, where N represents a positive integer which is not less than three, the second semiconductor pillar group being adjacent to the first semiconductor pillar group, the second semiconductor pillar group comprising (N+1)-th through 2N-th semiconductor pillars which are formed in the first direction with a space left therebetween, the first dummy pillar being disposed near a first particular semiconductor pillar in the first semiconductor pillar group in a second direction perpendicular to the first direction, the first particular semiconductor pillar being any one of the second through the (N−1)-th semiconductor pillars which are positioned in an intermediate portion exclusive of the first and the N-th semiconductor pillars, the second dumpy pillar being disposed near a second particular semiconductor pillar in the second semiconductor pillar group in the second direction at an opposite side of the first dummy pillar, the second particular semiconductor pillar being any one of the (N+2)-th through the (2N−1)-th semiconductor pillars which are positioned in an intermediate portion exclusive to the (N+1)-th and the 2N-th semiconductor pillars;

forming a first insulating film on a surface of the substrate that is exposed about the first through the 2N-th semiconductor pillars;

injecting impurities in the substrate via the first insulating film to form a drain diffused layer under the first insulating film;

forming gate insulting films on outer circumferential surfaces of the first through the 2N-th semiconductor pillars and on parts of outer circumferential surfaces of the first and the second dummy pillars; and

filling, via the gate insulating films, gaps between the first through the N-th semiconductor pillars and a gap between the first particular semiconductor pillar and the first dumpy pillar to form first gate electrodes over side faces of the first through the N-th semiconductor pillars and over a side face of the first dummy pillar; and

filling, via the gate insulating films, gaps between the (N+1)-th through the 2N-th semiconductor pillars and a gap between the second particular semiconductor pillar and the second dumpy pillar to form second gate electrodes over side faces of the (N+1)-th through the 2N-th semiconductor pillars and over a side face of the second dummy pillar.

What is claimed is:

1. A semiconductor device comprising:
a semiconductor pillar group comprising a plurality of semiconductor pillars which are formed in a first direction with a space left therebetween;
a dummy pillar disposed near a particular semiconductor pillar in the semiconductor pillar group in a second direction perpendicular to the first direction, the particular semiconductor pillar being any one of the semiconductor pillars which are positioned in an intermediate portion exclusive of both end portions;
gate insulating films which are formed on outer circumferential surfaces of the plurality of semiconductor pillars and one of which is formed on a part of an outer circumferential surface of the dummy pillar; and
gate electrodes which is formed over side faces of the plurality of semiconductor pillars and one of which is formed over a side face of the dummy pillar via the gate insulating films so as to fill gaps between the plurality of semiconductor pillars and a gap between the particular semiconductor pillar and the dummy pillar.

2. The semiconductor device as claimed in claim 1, wherein the dummy pillar is disposed at a position extending over an active region and an element isolation region, the dummy pillar comprising a composite pillar into which a dummy silicon pillar and an insulating layer pillar are incorporated.

3. The semiconductor device as claimed in claim 1, wherein the particular semiconductor pillar comprises one of the plurality of semiconductor pillars that is located at a central portion of the semiconductor pillar group.

4. The semiconductor device as claimed in claim 1, wherein the interval between adjacent semiconductor pillars is double or less the thickness of each gate electrode, the interval between the particular semiconductor pillar and the dummy pillar is double or less the thickness of each gate electrode.

5. The semiconductor device as claimed in claim 1, wherein further comprises:
a first insulating film formed on a substrate which is exposed about the respective semiconductor pillars; and
a drain diffused layer formed under the first insulating film, whereby the gate electrode and the drain diffused layer are insulated by the first insulating film.

6. The semiconductor device as claimed in claim 2, wherein further comprises:
a mask film disposed on the dummy pillar, the mask film together with the dummy pillar serving as a protrusion portion shoring up a height of the gate electrode;
an interlayer insulating film formed on the mask film;
a gate conductive plug penetrating the interlayer insulating film; and
a gate wire disposed on the interlayer insulating layer, the gate wire being connected via the gate conductive plug to the gate electrode which covers a side surface of the protrusion portion.

7. The semiconductor device as claimed in claim 6, wherein the gate conductive plug is disposed at a side of the insulating layer pillar.

8. The semiconductor device as claimed in claim 1,
wherein further comprises source diffused layers formed at upper portions of the plurality of semiconductor pillars,
wherein the gate electrodes have opening portions formed on upper faces of the plurality of semiconductor pillars,
wherein further comprises:
second insulating films formed on internal wall surfaces of the opening portions of the gate electrodes; and
silicon plugs formed in the opening portions of the gate electrodes via the second insulating films so as to be electrically connected to the source diffused layers, whereby the gate electrodes and the silicon plugs are insulated to each other by the second insulating films.

9. The semiconductor device as claimed in claim 1, wherein comprises a unit transistor group comprising a plurality of unit transistors corresponding to the plurality of semiconductor pillars, respectively, the unit transistor group constituting a single parallel transistor.

10. A semiconductor device comprising:
a first semiconductor pillar group comprising first through N-th semiconductor pillars which are formed in a first direction with a space left therebetween, where N represents a positive integer which is not less than three;
a second semiconductor pillar group adjacent to the first semiconductor pillar group, the second semiconductor pillar group comprising (N+1)-th through 2N-th semiconductor pillars which are formed in the first direction with a space left therebetween;
a first dummy pillar disposed near a first particular semiconductor pillar in the first semiconductor pillar group in a second direction perpendicular to the first direction, the first particular semiconductor pillar being any one of the second through the (N−1)-th semiconductor pillars which are positioned in an intermediate portion exclusive of the first and the N-th semiconductor pillars;
a second dumpy pillar disposed near a second particular semiconductor pillar in the second semiconductor pillar group in the second direction at an opposite side of the first dummy pillar, the second particular semiconductor pillar being any one of the (N+2)-th through the (2N−1)-th semiconductor pillars which are positioned in an intermediate portion exclusive to the (N+1)-th and the 2N-th semiconductor pillars;
gate insulating films which are formed on outer circumferential surfaces of the first through the 2N-th semiconductor pillars and two of which are formed on parts of outer circumferential surfaces of the first and the second dummy pillars; and
gate electrodes which are formed over side faces of the first through the 2N-th semiconductor pillars and two of which are formed over side faces of the first and the second dumpy pillars via the gate insulating films so as to fill gaps between the first through the 2N-th semiconductor pillars, a gap between the first particular semiconductor pillar and the first dumpy pillar, and a gap between the second particular semiconductor pillar and the second dummy pillar.

11. The semiconductor device as claimed in claim 10, wherein each of the first and the second dummy pillars is disposed at a position extending over an active region and an element isolation region, the first dummy pillar comprising a first composite pillar into which a first dummy silicon pillar and a first insulating layer pillar are incorporated, the second dummy pillar comprising a second composite pillar into which a second dummy silicon pillar and a second insulating layer pillar are incorporated.

12. The semiconductor device as claimed in claim 10,
wherein the first particular semiconductor pillar comprises one of the second through the (N−1)-th semiconductor pillars that is located at a central portion of the first semiconductor pillar group,
wherein the second particular semiconductor pillar comprises one of the (N+2)-th through (2N−1)-th semiconductor pillars that is located at a central portion of the second semiconductor pillar group.

13. The semiconductor device as claimed in claim 10, wherein the interval between adjacent semiconductor pillars is double or less the thickness of each gate electrode, the interval between the first particular semiconductor pillar and the first dummy pillar is double or less the thickness of each gate electrode, and the interval between the second particular semiconductor pillar and the second dummy pillar is double or less the thickness of each gate electrode

14. The semiconductor device as claimed in claim 10, wherein further comprises:
a first insulating film formed on a substrate which are exposed about the first through the 2N-th respective semiconductor pillars; and
a drain diffused layer formed under the first insulating film, whereby the gate electrodes and the drain diffused layer are insulated by the first insulating film.

15. The semiconductor device as clamed in claim 11, wherein further comprises:
mask films disposed on the first and the second dummy pillars, the mask films together with the first and the second dummy pillars serving as first and second protrusion portions shoring up a height of the gate electrodes;
an interlayer insulating film formed on the mask films;
a first gate conductive plug penetrating the interlayer insulating film;
a first gate wire disposed on the interlayer insulating layer, the first gate wire being connected via the first gate conductive plug to the gate electrode which covers a side face of the first protrusion portion;
a second gate conductive plug penetrating the interlayer insulating film; and
a second gate wire disposed on the interlayer insulating layer, the second gate wire being connected via the second gate conductive plug to the gate electrode which covers a side face of the second protrusion portion.

16. The semiconductor device as claimed in claim 15, wherein the first gate conductive plug is disposed at a side of the first insulating layer pillar, and the second gate conductive plug is disposed at a side of the second insulating layer pillar.

17. The semiconductor device as claimed in claim 10,
wherein further comprises source diffused layers formed at upper portions of the first through the 2N-th semiconductor pillars,
wherein the gate electrodes have opening portions formed upper faces of the first through the 2N-th semiconductor pillars,
wherein further comprises:
second insulating films formed on internal wall surfaces of the opening portions of the gate electrodes; and
silicon plugs formed in the opening portions of the gate electrodes via the second insulating films so as to be electrically connected to the source diffused layers, whereby the gate electrodes and the silicon plugs are insulated to each other by the second insulating films.

18. The semiconductor device as claimed in claim 10, wherein comprises:
a first unit transistor group comprising first through N-th unit transistors corresponding to the first through the N-th semiconductor pillars, respectively; and
a second unit transistor group comprising (N+1)-th through 2N-th unit transistors corresponding to the (N+1)-th through the 2N-th semiconductor pillars, respectively,
wherein the first unit transistor group and the second unit transistor group are connected in series to constitute a single serial/parallel transistor.

19. A semiconductor device comprising:
a first semiconductor pillar group comprising first through N-th semiconductor pillars which are formed in a first direction with a space left therebetween, where N represents a positive integer which is not less than three;
a second semiconductor pillar group adjacent to the first semiconductor pillar group, the second semiconductor pillar group comprising (N+1)-th through 2N-th semiconductor pillars which are formed in the first direction with a space left therebetween;
a first dummy pillar disposed near a first particular semiconductor pillar in the first semiconductor pillar group in a second direction perpendicular to the first direction, the first particular semiconductor pillar being any one of the second through the (N−1)-th semiconductor pillars which are positioned in an intermediate portion exclusive of the first and the N-th semiconductor pillars;
a second dumpy pillar disposed near a second particular semiconductor pillar in the second semiconductor pillar group in the second direction at an opposite side of the first dummy pillar, the second particular semiconductor pillar being any one of the (N+2)-th through the (2N−1)-th semiconductor pillars which are positioned in an intermediate portion exclusive to the (N+1)-th and the 2N-th semiconductor pillars;
gate insulating films which are formed on outer circumferential surfaces of the first through the 2N-th semiconductor pillars and two of which are formed on parts of outer circumferential surfaces of the first and the second dummy pillars;
first gate electrodes which are formed over side faces of the first through the N-th semiconductor pillars and one of which is formed over a side face of the first dumpy pillar via the gate insulating films so as to fill gaps between the first through the N-th semiconductor pillars and a gap between the first particular semiconductor pillar and the first dumpy pillar; and
second gate electrodes which are formed over side faces of the (N+1)-th through the 2N-th semiconductor pillars and one of which is formed over a side face of the second dumpy pillar via the gate insulating films so as to fill gaps between the (N+1)-th through the 2N-th semiconductor pillars and a gap between the second particular semiconductor pillar and the second dummy pillar,
wherein the interval between the first semiconductor pillar group and the second semiconductor pillar group is more double the thickness of each gate electrode.

20. The semiconductor device as claimed in claim 19, wherein each of the first and the second dummy pillars is disposed at a position extending over an active region and an element isolation region, the first dummy pillar comprising a first composite pillar into which a first dummy silicon pillar and a first insulating layer pillar are incorporated, the second dummy pillar comprising a second composite pillar into which a second dummy silicon pillar and a second insulating layer pillar are incorporated.
